(19) United States
(12) Patent Application Publication
(10) Pub. No.: US 2022/0147126 A1
(43) Pub. Date: May 12, 2022

(54) MEMORY THERMAL MANAGEMENT DURING INITIALIZATION OF AN INFORMATION HANDLING SYSTEM

(71) Applicant: Dell Products L.P., Round Rock, TX (US)

(72) Inventors: Jordan Chin, Austin, TX (US); Stuart Allen Berke, Austin, TX (US)

(73) Assignee: Dell Products L.P., Round Rock, TX (US)

(21) Appl. No.: 17/096,571

(22) Filed: Nov. 12, 2020

(51) Int. Cl. G06F 1/20; G06F 3/06

(52) U.S. Cl. CPC G06F 1/206; G06F 3/0673; G06F 3/0653; G06F 3/0616

(57) ABSTRACT

A memory of an information handling system may determine a memory test pattern for execution on the memory during a memory self-test procedure. The memory may execute the test pattern on the memory. While executing the test pattern on the memory, the memory may determine that a temperature of the memory has exceeded a predetermined temperature threshold. The memory may throttle execution of the test pattern based, at least in part, on the determination that the temperature of the memory has exceeded the first temperature threshold.

### FIELD OF THE DISCLOSURE

The present disclosure generally relates to information handling systems, and more particularly relates to thermal management of information handling system memory.

### BACKGROUND

As the value and use of information continue to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

Memory units, such as dual in-line memory modules (DIMMs), may be included in information handling systems for data storage. Memory units may, for example be dynamic random access memory (DRAM) memories. As information handling systems increase in complexity, greater numbers of memory units, of ever greater complexity, are incorporated in information handling systems. Memories, such as DIMMs, may be designed according to standards for memory design and operation, such as double data rate four (DDR4) and double data rate 5 (DDR5) standards developed by the Joint Electron Device Engineering Counsel (JEDEC).

Memories of information handling systems may implement self-testing procedures to determine whether faults are present. Such procedures may be implemented during a booting sequence of the information handling system, while the system is initializing. For example, a memory built-in self-test (MBIST) procedure may execute test patterns on memories of an information handling system to detect any defects that may exist in the memories. Self-repair procedures, such as post package repair and self-healing (mPPR), may be used to repair faults that are detected. MBIST and mPPR are two examples of self-test and self-repair functions included in DDR4 and/or DDR5. A mPPR process may repair defects found during a MBIST procedure. Self-testing and self-healing procedures may be performed early in a boot sequence, such as during a power-on self-test (POST) phase of a boot sequence prior to memory initialization to allow for detection and repair of faults in information handling system memories before the memories are initialized. Self-testing and self-repair procedures may be performed by memories without direction from an external host. Other memory repair procedures may also be implemented such as hard post-package repair and self-healing hPPR and soft post-package repair and self-healing sPPR, which may be directed by a host. Such direction may, for example, include instructions for the memory to test and/or fix a specific memory row location.

Given the increasing complexity of information handling system memories, the amount of power required to execute testing patterns on information handling system memories has likewise increased. In self-testing procedures, memories may read and write data at a high speed to detect faults. Such writing and reading may consume substantial power and, accordingly, may generate a substantial degree of heat. However, when memory self-testing procedures are performed cooling systems of an information handling system may not yet be initialized. Thus, the information handling system may be unable to respond to increases in memory temperatures caused by execution of memory self-testing procedures. In some cases, memories may exceed a desired operating temperature during execution of self-testing procedures due to unavailability of cooling systems. Such overheating may reduce the accuracy of memory self-testing procedures, causing the memory to detect faults that do not exist and/or fail to detect faults that do exist. Furthermore, overheating may damage a memory of an information handling system.

Shortcomings mentioned here are only representative and are included simply to highlight that a need exists for improved information handling systems. Embodiments described herein address certain shortcomings but not necessarily each and every one described here or known in the art. Furthermore, embodiments described herein may present other benefits than, and be used in other applications than, those of the shortcomings described above.

### SUMMARY

A memory of an information handling system may adjust execution of one or more test patterns executed during a memory self-test procedure based, at least in part, on a temperature of the memory. For example, if the memory determines that a temperature of the memory has exceeded a predetermined temperature threshold during execution of a test pattern, the memory may throttle execution of the test pattern. Such throttling may include reducing a speed at which the test pattern is executed. Throttling of execution of the test pattern may reduce an amount of heat generated during execution of the test pattern and may maintain the memory within a predetermined temperature range during execution of the test pattern, avoiding memory overheating. Avoiding memory overheating may enhance the accuracy of results of execution of the test pattern and/or prevent damage to the memory.

An example method for managing thermal performance of a memory of an information handling system may begin with a determination, by the memory, of a first test pattern to be executed on the memory during a memory self-test procedure. For example, early in an information handling system boot sequence and prior to memory initialization, the memory may select one or more test patterns to be executed on the memory during the memory self-test procedure. Prior to memory initialization the memory may be in a powered or semi-powered state but may not yet be selected or configured for use by the information handling system.

The memory may then execute the selected test pattern. For example, the memory may activate and deactivate cell arrays of the memory in a predetermined pattern according to the selected pattern, writing data to and reading data from the memory, to detect any faults that exist in the memory.

During execution of the first test pattern, the memory may determine that a temperature of the first memory has exceeded a first predetermined temperature threshold. For example, the memory may monitor a temperature of the memory using one or more internal or external temperature sensors. The temperature threshold may, for example, be a maximum operating temperature of the memory or a temperature related to the maximum operating temperature of the memory. The memory may continuously or periodically sense a temperature of the memory and compare the sensed temperature with the predetermined threshold to determine if and/or when a temperature of the memory exceeds the first predetermined temperature threshold.

When a determination is made that the temperature of the memory has exceeded the first predetermined temperature threshold, the memory may throttle execution of the first test pattern based, at least in part, on the determination. For example, the memory may reduce a speed of execution of the first test pattern to reduce an amount of heat generated by the first memory in order to reduce the temperature of the memory and/or maintain the temperature of the memory near or below the predetermined threshold.

In some embodiments, the memory may determine a maximum time period for the self-test procedure. The first test pattern may, for example, be a test period to be executed during a first portion of the maximum time period. The first portion of the maximum time period may have a length less than a total length of the maximum time period. In some embodiments, throttling execution of the first test pattern may include reducing a speed of execution of the first test pattern such that the first test pattern will be completed within the maximum time period for the memory self-test procedure. For example, throttling the execution of the first test pattern may cause execution of the first test pattern to extend beyond a length of the first portion of the maximum time period while completing before or at an end of the maximum time period.

In some embodiments, multiple test patterns may be determined for execution by the memory. For example, the memory may determine a first test pattern and a second test pattern for sequential execution during the memory self-test procedure. In some embodiments the first test pattern may be a mandatory test pattern while the second test pattern may be an optional test pattern. The second test pattern may, for example, be a second test pattern to be executed during a second portion of the maximum time period following the first portion of the maximum time period. When first and second test patterns are determined for execution, and the memory throttles the first test pattern, the memory may determine not to execute the second test pattern. For example, the second test pattern may be dropped from execution if a determination is made by the memory that a time require to complete execution of the throttled first test pattern and the second test pattern is greater than an amount of time remaining in the maximum time period. Thus, priority may be given to temperature reduction by throttling the first test pattern and dropping the second test pattern from execution, so that execution of test patterns will be completed within the maximum time period.

In some embodiments, the memory may determine that throttled execution of the first test pattern will not complete within a maximum time period. For example, in some cases completion of execution of a throttled first test pattern may require more time than an amount of time remaining in the maximum time period. When the memory determines that execution of the throttled first test pattern will not be completed during the maximum time period, the memory may notify a processor of the information handling system that the memory self-test procedure should be repeated. Thus, the processor will be informed of a failure to complete execution of a test pattern and may repeat the memory self-test procedure to allow completion of the test pattern.

In some embodiments, the memory may increase a refresh rate of the memory instead of or in addition to throttling execution of the first test pattern. For example, the memory may determine during execution of the first test pattern that a temperature of the memory has exceeded a second temperature threshold. In some embodiments the second temperature threshold may be greater than, less than, or equal to the first temperature threshold. Based on the determination that the temperature of the memory has exceeded the second temperature threshold, the memory may increase a refresh rate of the memory for the remainder of execution of the first test pattern. Increasing a refresh rate of the memory may increase a maximum operating temperature of the memory, allowing for greater heat generation while still obtaining reliable results from execution of the first test pattern.

An information handling system may include a processor and/or a memory for performing the steps described herein. Alternatively or additionally, a computer program product may include a non-transitory computer-readable medium comprising instructions to cause a memory to perform the steps described herein.

The foregoing has outlined rather broadly certain features and technical advantages of embodiments of the present invention in order that the detailed description that follows may be better understood. Additional features and advantages will be described hereinafter that form the subject of the claims of the invention. It should be appreciated by those having ordinary skill in the art that the conception and specific embodiment disclosed may be readily utilized as a basis for modifying or designing other structures for carrying out the same or similar purposes. It should also be realized by those having ordinary skill in the art that such equivalent constructions do not depart from the spirit and scope of the invention as set forth in the appended claims. Additional features will be better understood from the following description when considered in connection with the accompanying figures. It is to be expressly understood, however, that each of the figures is provided for the purpose of illustration and description only and is not intended to limit the present invention.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram of an example memory of an information handling system connected to a processor and a controller via a multiplexer according to some embodiments of the disclosure.

FIG. 2 is a block diagram of an example memory of an information handling system connected to a controller via a processor according to some embodiments of the disclosure.

FIG. 3A is a timing diagram of execution of a memory self-test procedure having a first test pattern according to some embodiments of the disclosure.

FIG. 3B is a timing diagram of execution of a memory self-test procedure with a throttled first test pattern according to some embodiments of the disclosure.

FIG. 4A is a timing diagram of execution of a memory self-test procedure with first and second test patterns according to some embodiments of the disclosure.

FIG. 4B is a timing diagram of execution of a memory self-test procedure with a throttled first test pattern causing a second test pattern to be dropped from execution according to some embodiments of the disclosure.

FIG. 5 is a timing diagram of execution of a memory self-test procedure with a first test pattern requiring more time for execution than available within a maximum time period for the memory self-test procedure according to some embodiments of the disclosure.

FIG. 6 is a block diagram of an example method for managing memory thermal performance during a memory self-test procedure according to some embodiments of the disclosure.

FIG. 7 is a block diagram of an example method for managing memory thermal performance during a memory self-test procedure where multiple test patterns are selected according to some embodiments of the disclosure.

FIG. 8 is a block diagram of an example method for notifying a processor of a failure to complete execution of a test pattern during a memory self-test procedure according to some embodiments of the disclosure.

FIG. 9 is a block diagram of an example method for managing memory thermal performance during a memory self-test procedure by adjusting a refresh rate of the memory according to some embodiments of the disclosure.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be used in this application. The teachings can also be used in other applications and with several different types of architectures.

For purposes of this disclosure, an information handling system (IHS) may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (e.g., desktop or laptop), tablet computer, a two-in-one laptop/tablet computer, mobile device (e.g., personal digital assistant (PDA), smart phone, tablet computer, or smart watch), server (e.g., blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more virtual or physical buses operable to transmit communications between the various hardware and/or software components.

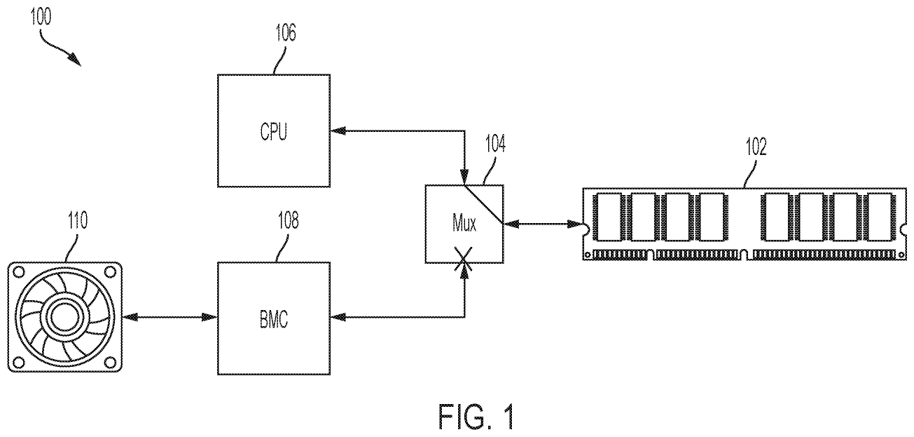

Early in a booting process, one or more memories of an information handling system may execute a self-test procedure, such as a MBIST procedure, and/or a self-healing procedure, such as an mPPR procedure, to detect and/or repair defects in the one or more memories prior to memory initialization and utilization by the information handling system. Self-test and self-healing procedures may be directed and executed by the memories of the information handling system themselves, without receipt of external instructions from sources such as processors and/or controllers specifying specific portions of the memory for testing and/or repair. A memory self-test procedure may be performed prior to memory initialization, such as early in a power-on self-test (POST) boot phase, while a processor of the information handling system is operating entirely out of a processor cache. When the memory self-test procedure is performed, thermal monitoring and management capabilities of the information handling system may be limited, or even completely unavailable. For example, as shown in the information handling system 100 of FIG. 1, a memory 102 of an information handling system 100, such as a dual in-line memory module (DIMM), may be connected to a central processing unit (CPU) 106 and a baseboard management controller 108 of the information handling system via a multiplexer. When the memory self-test procedure is performed, the memory 102 may be connected to the CPU 106 via the multiplexer 104, but not to the baseboard management controller 108. The baseboard management controller 108 may, for example, be configured to control one or more thermal management systems 110 of the information handling system 100. Thermal management systems 110 of the information handling system may monitor temperatures of components of the information handling system and provide cooling to maintain temperatures below predetermined temperature thresholds. Thermal management systems 110 may include fan cooling systems, liquid cooling systems, and other cooling systems. Thermal management systems 110 may also include thermal sensors for monitoring temperatures throughout the information handling system or may communicate with components of the information handling system 100 to receive internal temperature data for the components.

While the memory self-test procedure is being performed, communication between the memory 102 and the BMC 108, and, by extension, the thermal management systems 208 is unavailable. For example, a direct BMC 108 sideband bus access to thermal sensors of the memory 102 is unavailable. For example, a basic input output system (BIOS) executed by the CPU 106 may require sideband bus access for the memory 102 for serial presence detect (SPD) read/write and read/write functionality of a power management integrated circuit (PMIC) of the memory 102. Furthermore, multi-master capabilities may not be supported by a sideband bus of the memory 102. Thus, even if the thermal management systems are operational, they are unable to communicate with the memory 102 and provide cooling to the memory 102 as needed. Thus, when a self-test procedure is being performed by the memory 102, thermal management systems 110 are not available to respond to and/or counteract increases in temperature in the memory 102. Unavailability of thermal management systems 208 leads to memory overheating leads to memory temperatures that exceed predetermined temperature thresholds. For example, 256 gigabyte DIMMs having two ranks of four-high stacks 16 gigabit DRAM dies with eight logical ranks may encounter overheating during such testing. Such temperatures decrease the accuracy of memory self-testing procedures and may damage the memory.

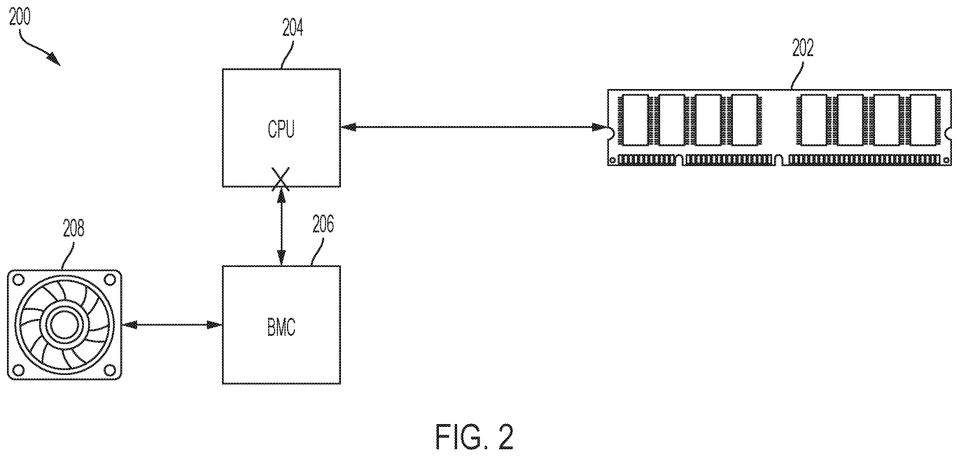

In some platforms, such as shown in the information handling system 200 of FIG. 2, a memory 202 may communicate with a BMC 206, and, by extension, one or more thermal management systems 208 via a CPU 204. However, communication between the CPU 204 and the BMC 206 may not yet be activated when the memory 202 is performing a memory self-test procedure during a booting process. For example, the thermal management systems 208 may rely on temperature auto-polling on the CPU 204 and BMC 206 proxies of temperature from the CPU 204 for operation of the thermal management systems 208. The thermal management systems 208 may rely on temperature data received from the CPU 204, the BMC 206, and/or the memory 202 to govern operation of the thermal management systems 208. Channels for communication of such data may be unavailable while the memory 202 is performing a memory self-test procedure, such as during or prior to a POST boot phase. The lack of availability of channels for such communication may be due to cache limitations and/or sideband bus contention within various control units of the information handling system, such as within CPU 204. Thus, thermal management systems 208 may not be available to a memory of an information handling system early in a boot sequence, such as when the memory is performing a memory self-test procedure. Unavailability of thermal management systems 110 leads to memory overheating leads to memory temperatures that exceed predetermined temperature thresholds. Such temperatures decrease the accuracy of memory self-testing procedures and may damage the memory.

Internal temperature sensors of a memory, such as memory 102 of FIG. 1 or memory 202 of FIG. 2, may be used by the memory to monitor a temperature of the memory during a memory self-test procedure, such as during execution of one or more MBIST test patterns. If the memory determines that a temperature has exceeded a predetermined temperature threshold, the memory may adjust performance of the memory self-test procedure to reduce heat generation and/or increase a heat tolerance of the memory. For example, a maximum operating temperature of the memory may be 85 degrees Celsius, or another temperature. If the maximum operating temperature is exceeded during operation, results of the memory self-test procedure may be unreliable, and the memory may fail to detect faults that exist and/or may report faults where no faults exist.

A memory self-test procedure, such as an MBIST, may be executed by a memory early in a boot sequence, such as early in a POST phase of a boot sequence, before memories of an information handling system are initialized. A POST phase of a boot sequence may include verifying CPU registers, verifying an integrity of BIOS code, verifying system component functionality, such as timers and interrupt controllers, locating, sizing, and verifying system main memory, initialization of a BIOS, and identification, organization, and selection of devices that are available for booting. Memory self-testing procedures may be performed during verification of a system main memory. A maximum time for performance of a self-test procedure, tSELFTEST, may be predetermined. For example, a standard such as a Joint Electron Device Engineering Counsel (JEDEC) standard for design and operation of information handling system memories, such as DIMMs, may specify a maximum time for performance of a self-test procedure, and an indicator of the maximum time may be stored in the memory. The maximum time period for performance of the self-test procedure, tSELFTEST, may be determined based on a density of the memory, such as a density of the DRAM. For example, the maximum time may be determined per logical rank, where tSELFTEST includes a predetermined number of seconds for each logical rank. For example, a tSELFTEST may be nine seconds per rank per DIMM for a 16 gigabit DRAM density, 14 seconds per rank per DIMM for a 24 gigabit DRAM density, and 19 seconds per rank per DIMM for a 32 gigabit DRAM density. The maximum time period may, for example, be a pre-programmed value stored in a register of the memory, or in another storage location.

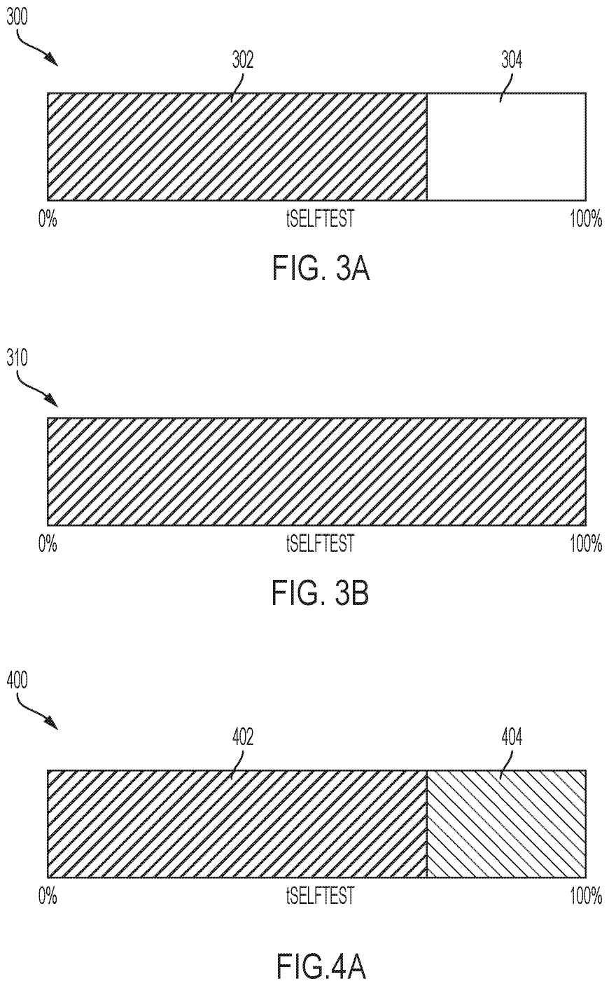

An example maximum time period 300 for performance of a self-test procedure, tSELFTEST, is shown in FIG. 3A. A first test pattern may be selected for execution on the memory during the maximum time period 304 for performance of the self-test procedure. Execution of the first test pattern may consume a first portion 302 of the maximum time period 304, less than the total amount of time available in the maximum time period 304. Thus, a second portion 304 of the maximum time period 300 may not be scheduled for use during the self-test procedure. For example, at an initial rate of execution, execution of the first test pattern may be expected to consume a percentage of the maximum time period 304, such as 60%. The first test pattern may, for example, be a Modified Algorithmic Test Sequence Plus (MATS+) test pattern, a Modified Algorithmic Test Sequence Plus Plus (MATS++) test pattern, a MarchC− test pattern, a MarchX test pattern, a MarchC test pattern, a MarchA test pattern, a MarchY test pattern, a MarchB test pattern, a butterfly test pattern, a moving inversion test pattern, a surround disturb test pattern, or another test pattern. For example, a MATS+ test pattern may test for unlinked stuck-at faults where logical gates of a memory are stuck at 0 or 1, by marching through and reading from/writing to all or part of the cells of the memory and different combinations of cells of the memory in a predetermined pattern. The MATS+ test may detect all be a marching test algorithm with a complexity of 5n. A MarchC− test pattern may test for unlinked stuck-at faults, where logical gates of a memory are stuck at 0 or 1, transition faults where a cell fails to transition from 0 to 1, and other faults by marching through and reading from/writing to all or part of the cells of the memory and different combinations of cells of the memory in a predetermined pattern. The MarchC− test pattern may have a complexity of 10n. The first test pattern may, for example, be a mandatory test pattern that must be performed. In some embodiments, multiple test patterns may be selected for execution during the first portion 302 of the maximum time period 300.

While the first test pattern is being executed by the memory, the memory may detect that a temperature of the memory has exceeded a predetermined threshold. For example, the memory may monitor one or more temperature sensors of the memory, such as on-die temperature sensors periodically or continuously while the first test pattern is being executed. The predetermined threshold may be 80 degrees Celsius, 85 degrees Celsius, or another temperature. When the memory determines that the temperature of the memory has exceeded a predetermined temperature threshold, such as a maximum operating temperature or a temperature threshold related to the maximum operating temperature, the memory may adjust execution of the first test pattern. For example, the memory may throttle execution of the first test pattern, reducing a speed of execution of the first test pattern. For example, the memory may determine that a portion 304 of the maximum time period is not scheduled to be used and may throttle execution of the first test pattern so that execution of the first test pattern consumes at least part of the second portion 304 of the maximum time period. For example, as shown in FIG. 3B, execution of the first test pattern may be throttled such that a first time period 310 for execution of the first test pattern consumes an entirety of the maximum time period for execution of the self-test procedure. Throttling the execution of the first test pattern may reduce an amount of heat generated during execution of the first test pattern and thus may reduce a temperature of the memory, allowing the memory to maintain a temperature of the memory within a predetermined temperature range or below a predetermined temperature threshold during execution of the memory self-test procedure. Throttling of execution of test patterns may allow for reduction in a temperature of the memory without requiring use or control of external cooling systems, such as thermal management systems, of the information handling system.

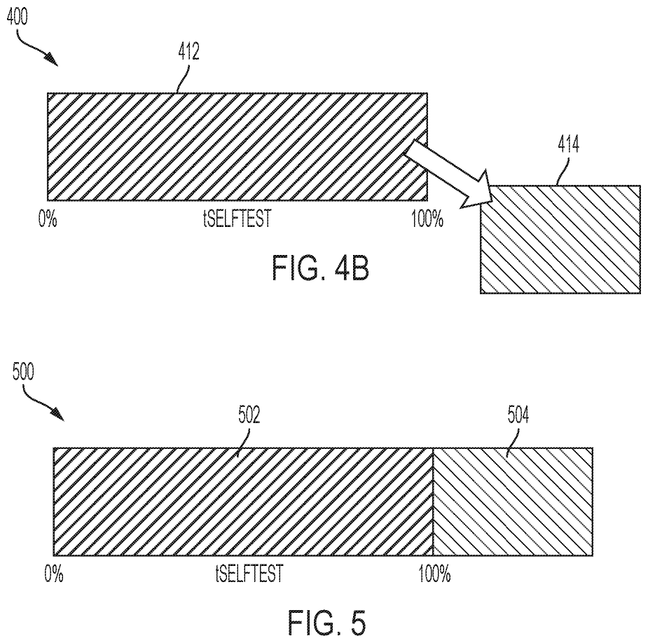

In some embodiments, multiple test patterns may be selected for execution during a memory self-test procedure. For example, a memory may select a first test pattern to be executed during a first portion 402 of a maximum time period 400 for execution of the memory self-test procedure and a second test pattern to be executed during a second portion 404 of the maximum time period 400 following execution of the first test pattern, as shown in FIG. 4A. In some embodiments, the first portion 402 and the second portion 404 may consume an entirety of the maximum time period 400, while in other embodiments additional time may be left over in the maximum time period 400 following portions of the maximum time period for execution of the first and second test patterns. In some embodiments, the first test pattern may be a mandatory test pattern while the second test pattern may be an optional test pattern. In some embodiments, the first test pattern may be a less complex test pattern, while the second test pattern may be a more complex test pattern for more exhaustively testing the memory. In some embodiments the first test pattern may be a MATS+ test pattern while the second test pattern may be a MarchC− test pattern.

During execution of the first test pattern, the memory may detect that a temperature of the memory has exceeded a predetermined threshold. Based on detection that the memory has exceeded the predetermined threshold, the memory may determine to adjust execution of the first test pattern to reduce an amount of heat generated by execution of the first test pattern, such as by throttling execution of the first test pattern. The memory may, for example, determine that a time period 412 for execution of the first test pattern when throttled, and a time period 414 for execution of the second test pattern would exceed the maximum time period 410, as shown in FIG. 4B. In some embodiments, the first time period 412 for execution of the first test pattern, when throttled, may consume all or a portion of the maximum time period 410. The memory may determine that the second test pattern is optional and may not execute the second test pattern, as shown in FIG. 4B. The memory may then complete execution of the throttled first test pattern.

In some embodiments, the memory may determine that the first test pattern will not complete execution during the maximum time period. For example, the memory may determine that a time period 500 required for execution of the first test pattern may exceed a maximum time period 502 for the memory self-test procedure by a first amount 504, as shown in FIG. 5. In some embodiments, the memory may determine that a time period 500 for execution of a first test pattern when not throttled will exceed the maximum time period 502. In other embodiments, the memory may determine that a time period 500 for execution of a first test pattern when throttled will exceed a maximum time period 500 for the memory self-test procedure. For example, the memory may determine that execution of a mandatory test pattern requires more time than is available in the maximum time period for execution of the self-test procedure. When such a determination is made, the memory may notify a processor of the information handling system that the memory self-test procedure has not been completed and should be run again. Thus, the processor may return to the memory self-test procedure to allow completion.

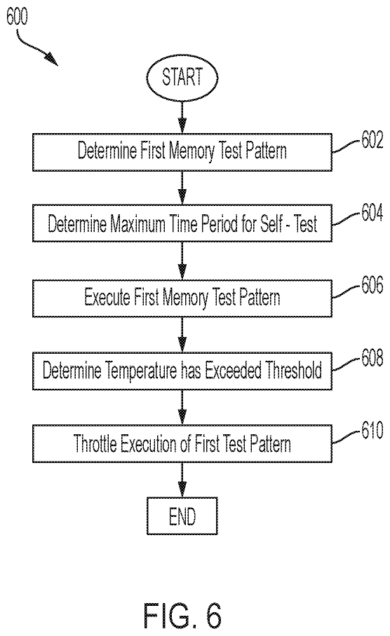

A memory of an information handling system may adjust execution of a memory self-test procedure to prevent overheating of the memory. An example method 600 for throttling execution of a test pattern of a memory self-test procedure is shown in FIG. 6. The method 600 may begin, at step 602, with determination of a first memory test pattern. For example, a memory self-test procedure may be performed early in a booting sequence, such as during a POST phase of a booting sequence, prior to full initialization of the memory. The memory may select a memory test pattern, such as a MATS+ pattern, a MarchC− pattern, or another test pattern for execution during the memory self-test procedure. The memory test pattern may, for example, be a power-intensive function where the memory repeatedly writes and reads numerous patterns of the memory test pattern throughout cell arrays of the memory for up to multiple minutes of test execution time to determine whether any faults exist in the memory. Due to the power intensive nature of execution of the test pattern, substantial heat may be generated during execution of the first memory test pattern. However, thermal management systems of the information handling system may not yet be available and/or may be unable to receive temperature data from the memory.

At step 604, the memory may determine a maximum time period for the self-test procedure. Such a time period may, for example, be predetermined and stored in the memory or in another data storage location. The first memory test pattern may be determined for execution during a first portion of the maximum time period. For example, at an initial speed of execution the first test pattern may be determined to complete prior to expiration of the maximum time period. Determining a maximum time period for the self-test procedure may include reading a pre-programmed maximum time value from a register of the memory or another storage location.

At step 606, the memory may begin execution of the first test pattern. For example, the memory may begin execution of the first test pattern at a first speed, such as a standard speed for execution of the first test pattern. The memory may begin execution of the first test pattern at or following a beginning of the maximum time period for execution of the memory self-test procedure.

At step 608, the memory may determine that a temperature of the memory has exceeded a threshold temperature. For example, the memory may monitor one or more temperature sensors of the memory, such as one or more on-die temperature sensors of the memory during execution of the first test pattern. A temperature of the memory may increase as power is consumed during execution of the first test pattern. The memory may determine when the temperature exceeds a first temperature threshold. The first temperature threshold may be, or may be related to, a maximum operating temperature of the memory. For example, the first temperature threshold may be 80 degrees Celsius, 85 degrees Celsius, or another temperature threshold. In some embodiments, the temperature threshold may vary based on a refresh rate at which the memory is operating during execution of the first test pattern.

At step 610, the memory may throttle execution of the first test pattern based, at least in part, on the determination that the temperature of the memory has exceeded the first temperature threshold. For example, the memory may slow a rate of execution of the first test pattern. Such a reduction may reduce an amount of heat generated by the first test pattern. In some embodiments, the memory may determine an amount of time remaining in the maximum time period and may adjust the rate of execution of the test pattern such that execution of the remainder of the test pattern will consume all, or part of, the time remaining in the maximum time period for execution of the memory self-test procedure. For example, the memory may reduce a rate of execution of the first test pattern to a minimum speed. Reduction of a rate of execution of the first test pattern may, for example, include slowing a pattern generator for the first test pattern such that execution of the remainder of the first test pattern may be spread across an entirety of a remaining time of the maximum time period for execution of the self-test procedure. In some embodiments, steps 608-610 of the method 600 may be repeated and execution of the first test pattern may be further throttled if a temperature of the memory exceeds a second threshold, which may be equal to, less than, or greater than the first threshold, following throttling of execution of the first test pattern.

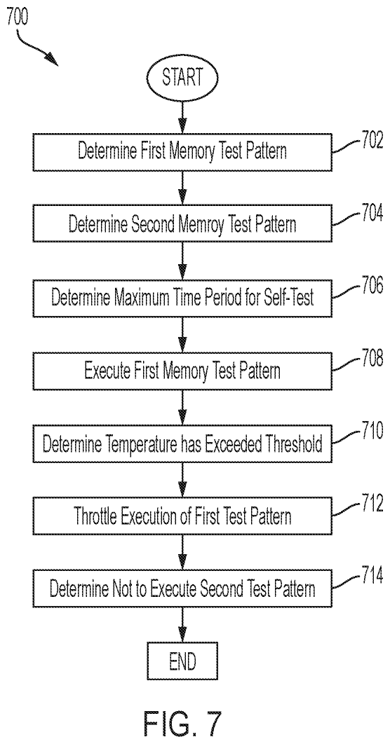

In some embodiments, multiple test patterns for execution during the memory self-test procedure may be selected by the memory. An example method 700 for adjusting execution of a plurality of selected test patterns based on a detected memory temperature is shown in FIG. 7. The method 700 may begin, at step 702, with determination of a first memory test pattern for execution during a memory self-test procedure. At step 704, the memory may determine a second memory test pattern for execution. The first memory test pattern may, for example, be a mandatory memory test pattern, while the second memory test pattern may be an optional memory test pattern. At step 706, the memory may determine a maximum time period for the self-test procedure. In some embodiments, the first memory test pattern may be a test pattern for execution in a first portion of the maximum time period, while the second memory test pattern may be a test pattern for execution in a second portion of the maximum time period, following the first portion of the maximum time period. In some embodiments, the sum of the first portion and the second portion of the maximum time period may be equal to the maximum time period, while in other embodiments, the sum of the first portion and the second portion may be less than the maximum time period.

At step 708, the memory may begin execution of the first memory test pattern. During execution of the first memory test pattern, the memory may, at step 710, determine that a temperature of the memory has exceeded a first temperature threshold. At step 712, the memory may, in response to the determination that the memory has exceeded the first threshold temperature, throttle execution of the first test pattern. For example, as discussed above with respect to step 610 of FIG. 6, the memory may slow execution of the first test pattern such that throttled execution of the first test pattern takes up all, or part, of a remainder of the maximum time period. At step 714, the memory may determine not to execute the second test pattern. For example the memory may determine whether, when the first test pattern is throttled, sufficient time remains in the maximum time period for execution of the second test pattern. If sufficient time does not remain in the maximum time period for execution of the second test pattern following completion of execution of the throttled first test pattern, the memory may drop the second test pattern from execution. For example, if executing the second test pattern following execution of the throttled first test pattern would consume more time than is remaining in the maximum time period, the memory may choose not to execute the second test pattern on the memory. In some embodiments, the memory may determine whether sufficient time remains in the maximum time period for execution of the second test pattern, if the second test pattern is throttled, and may determine not to execute the second test pattern if insufficient time remains to execute the throttled second test pattern. Thus, the memory may determine to drop a second test pattern if insufficient time remains in a maximum time period for execution of a memory self-test procedure for execution of both a throttled first test pattern and the second test pattern.

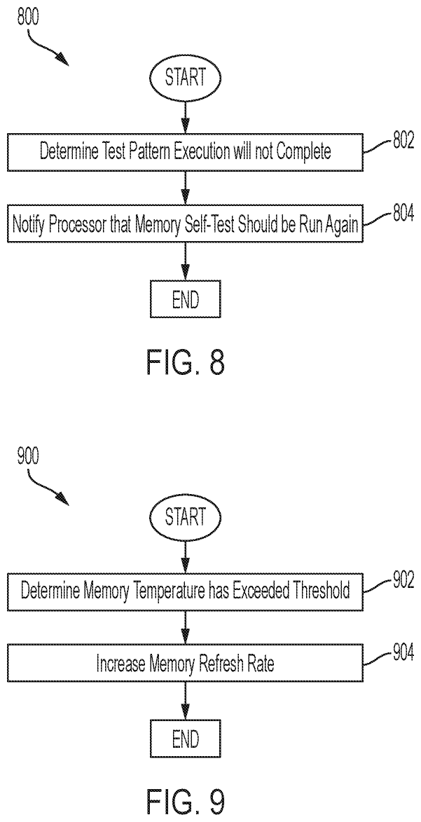

In some embodiments, a memory may determine that there is insufficient time in a maximum time period to complete execution of a first test pattern, and the memory may notify a processor of an information handling system that the self-test procedure should be repeated. An example method 800 for notifying a processor of an information handling system that a memory self-test procedure should be repeated is shown in FIG. 8. The method 800 may begin, at step 802, with determining that execution of a first test pattern will not complete within a maximum time period for execution of a memory self-test procedure. In some embodiments, a memory may determine that execution of one or more mandatory test patterns will not complete at a predetermined standard speed within a maximum time period for completion of a memory self-test procedure. In some embodiments, a memory may determine that execution of one or more mandatory test patterns will not complete within the maximum time period when one or more of the predetermined test patterns has been throttled due to a determined temperature of the memory exceeding a predetermined threshold. At step 804, the memory may notify a processor of an information handling system that the memory self-test procedure should be run again. Repeating the memory self-test procedure may allow the memory to complete the self-test procedure to verify that any faults in the memory have been detected.

In some embodiments, a refresh rate of the memory may be adjusted when a temperature of the memory exceeds a predetermined threshold in place of, or in addition to, throttling execution of one or more test patterns. An example method 900 for adjusting a refresh rate of a memory is shown in FIG. 9. The method 900 may begin, at step 902, with determination that a memory temperature has exceeded a predetermined temperature threshold. For example, a determination may be made that a temperature of the memory has exceeded 80 degrees Celsius, 85 degrees Celsius, or another temperature threshold. A determination that the memory has exceeded a predetermined temperature threshold may be made while the memory is executing one or more test patterns during a memory self-test procedure.

At step 904, the memory may increase a refresh rate of the memory based, at least in part, on the determination that the temperature of the memory has exceeded a predetermined threshold. For example, the memory may double the refresh rate, triple the refresh rate, or adjust the refresh rate by another rate.

Adjustment of the memory refresh rate, as described with respect to FIG. 9 may be performed along with adjustment of a rate of execution of memory test patterns, as described with respect to FIGS. 6-7. For example, if a temperature of the memory continues to increase after a refresh rate of the memory is adjusted, the memory may perform one or more steps as described with respect to FIGS. 6-7. Likewise, if a temperature of the memory continues to increase after a rate of execution of one or more test patterns is adjusted, as described with respect to FIGS. 6-7, the memory may perform one or more steps related to adjusting a refresh rate of the memory, as described with respect to FIG. 9. In some embodiments, a memory temperature threshold for determining to increase a refresh rate of the memory may be the same as a temperature threshold for determining to throttle execution of one or more memory test patterns. In other embodiments, the temperature threshold for determining to increase a refresh rate of the memory may be higher or lower than a temperature threshold for determining to throttle execution of one or more memory test patterns. Increasing a refresh rate of the memory may increase a maximum operating temperature of the memory. Thus, for example, if a memory approaches a first temperature threshold, for example a temperature threshold of 85 degrees Celsius, the memory may increase a refresh rate of the memory, increasing a maximum operating temperature of the memory above 85 degrees Celsius. If a temperature of the memory then exceeds a second temperature threshold, for example a temperature threshold of 90 or 95 degrees Celsius, during execution of one or more test patterns, the memory may throttle execution of the first test pattern. Thus, increasing a memory refresh rate may be used alone, or in addition to throttling execution of a test pattern to manage thermal performance of a memory of an information handling system.

The flow chart diagrams of FIGS. 6-9 are generally set forth as logical flow chart diagrams. As such, the depicted order and labeled steps are indicative of aspects of the disclosed method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagram, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

If implemented in firmware and/or software, functions described above may be stored as one or more instructions or code on a computer-readable medium. Examples include non-transitory computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise random access memory (RAM), read-only memory (ROM), electrically-erasable programmable read-only memory (EEPROM), compact disc read-only memory (CD-ROM) or other optical disk storage, magnetic disk storage or other magnetic storage devices, or any other medium that can be used to store desired program code in the form of instructions or data structures and that can be accessed by a computer. Disk and disc includes compact discs (CD), laser discs, optical discs, digital versatile discs (DVD), floppy disks and Blu-ray discs. Generally, disks reproduce data magnetically, and discs reproduce data optically. Combinations of the above should also be included within the scope of computer-readable media.

Memory may include dynamic random access memory (DRAM), static random access memory (SRAM), phase change memory (PCM), carbon nanotube memory (NRAM), magnetic random access memory (MRAM), or a different memory. Memories may have a discrete form factor, such as a DIMM form factor, may be integrated into other information handling system components, such as central processing units (CPUs), field programmable gate arrays (FPGAs), graphics processing units (GPUs), or may be memories having another form factor. For example, memories may be found in an on-package memory form factor, a multi-chip module form factor, such as a chiplet form factor, or another factor.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and certain representative advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

What is claimed is:

1. A method for managing thermal performance of a memory of an information handling system, comprising:
determining, by the memory, a first test pattern to be executed on the memory during a memory self-test procedure;
executing, by the memory, the first test pattern on the memory;
determining, by the memory during execution of the first test pattern, that a first temperature of the memory has exceeded a first predetermined temperature threshold; and
throttling execution of the first test pattern based, at least in part, on the determination that the memory has exceeded the first predetermined temperature threshold.

2. The method of claim 1, further comprising determining a maximum time period for the self-test procedure, wherein the first test pattern is determined for execution during a first portion of the maximum time period for the self-test procedure, and wherein a length of the first portion of the maximum time period is less than a length of the maximum time period.

3. The method of claim 2, wherein throttling execution of the first test pattern comprises reducing a speed of execution of the first test pattern such that execution of the first test pattern will be completed within the maximum time period for the self-test procedure.

4. The method of claim 2, further comprising:
determining, by the memory, a second test pattern to be executed on the memory during the memory self-test procedure, wherein the second test pattern is determined for execution during a second portion of the maximum time period following the first portion of the maximum time period; and
determining, by the memory, not to execute the second test pattern.

5. The method of claim 4, wherein determining not to execute the second test pattern comprises determining that an amount of time required to complete execution of the second test pattern following completion of execution of the throttled first test pattern is greater than an amount of time remaining in the maximum time period for the self-test procedure following completion of execution of the throttled first test pattern.

6. The method of claim 2, further comprising:
determining, by the memory, that the throttled execution of the first test pattern will not complete within the maximum time period; and
notifying, by the memory, a processor of the information handling system that the memory self-test procedure should be repeated.

7. The method of claim 1, further comprising:
determining, by the memory during execution of the first test pattern, that a temperature of the memory has exceeded a second temperature threshold; and
increasing a refresh rate of the memory for the remainder of execution of the first test pattern.

8. The method of claim 1, wherein the step of throttling is performed during a power-on self-test (POST) phase of a boot sequence.

9. An information handling system, comprising:
a memory;
wherein the memory is configured to perform steps comprising:
determining a first test pattern to be executed on the memory during a memory self-test procedure;
executing the first test pattern on the memory;
determining during execution of the first test pattern, that a first temperature of the memory has exceeded a first predetermined temperature threshold; and
throttling execution of the first test pattern based, at least in part, on the determination that the memory has exceeded the first predetermined temperature threshold.

10. The information handling system of claim 9, wherein the memory is further configured to perform steps comprising determining a maximum time period for the self-test procedure, wherein the first test pattern is determined for execution during a first portion of the maximum time period for the self-test procedure, and wherein a length of the first portion of the maximum time period is less than a length of the maximum time period.

11. The information handling system of claim 10, wherein throttling execution of the first test pattern comprises reducing a speed of execution of the first test pattern such that execution of the first test pattern will be completed within the maximum time period for the self-test procedure.

12. The information handling system of claim 10, wherein the memory is further configured to perform steps comprising:
determining a second test pattern to be executed on the memory during the memory self-test procedure, wherein the second test pattern is determined for execution during a second portion of the maximum time period following the first portion of the maximum time period; and
determining, by the memory, not to execute the second test pattern.

13. The information handling system of claim 12, wherein determining not to execute the second test pattern comprises determining that an amount of time required to complete execution of the second test pattern following completion of execution of the throttled first test pattern is greater than an amount of time remaining in the maximum time period for the self-test procedure following completion of execution of the throttled first test pattern.

14. The information handling system of claim 10, wherein the memory is further configured to perform steps comprising:
determining that the throttled execution of the first test pattern will not complete within the maximum time period; and
notifying a processor of the information handling system that the memory self-test procedure should be repeated.

15. The information handling system of claim 9, wherein the memory is further configured to perform steps comprising:
determining, during execution of the first test pattern, that a temperature of the memory has exceeded a second temperature threshold; and
increasing a refresh rate of the memory for the remainder of execution of the first test pattern.

16. The information handling system of claim 9, wherein the step of throttling is performed during a power-on self-test (POST) phase of a boot sequence.

17. A method for managing thermal performance of a memory, comprising:
determining, by a memory of an information handling system, a first test pattern to be executed on the memory during a memory self-test procedure;
executing, by the memory, the first test pattern on the memory;
determining, by the memory during execution of the first test pattern, that a first temperature of the memory has exceeded a first predetermined temperature threshold; and
increasing a refresh rate of the memory for the remainder of execution of the first test pattern.

18. The method of claim 17, further comprising:
determining, during execution of the first test pattern, that a temperature of the memory has exceeded a second temperature threshold; and
throttling execution of the first test pattern based, at least in part, on the determination that the memory has exceeded the second predetermined temperature threshold.

19. The method of claim 17, wherein increasing the refresh rate comprises doubling the refresh rate.

20. The method of claim 17, wherein the step of increasing the refresh rate is performed during a power-on self-test (POST) phase of a boot sequence.
